(19) United States
(12) Patent Application Publication
(10) Pub. No.: US 2010/0294529 A1
(43) Pub. Date: Nov. 25, 2010

(54) TERMINAL BOX FOR SOLAR CELL MODULE

(76) Inventor: Chiharu Nunokawa, Tokyo (JP)

Correspondence Address: WENDEROTH, LIND & PONACK, L.L.P., 1030 15th Street, N.W.,, Suite 400 East, Washington, DC, 20005-1503, US

(21) Appl. No.: 12/863,608

(22) PCT Filed: Mar. 16, 2009
(86) PCT No.: PCT/JP2009/055032

§ 371 Date: Jul. 20, 2010

(30) Foreign Application Priority Data
Apr. 3, 2008 (JP) 2008-096979

(51) Int. Cl. H02G 3/18; H05K 13/00

(52) U.S. Cl. 174/60; 29/592.1; 174/59

(57) ABSTRACT

Disclosed is a terminal box (1) for solar cell module wherein a recessed inserting portion (2d) opening upward in order to insert a connection cable (5) is formed in sidewalls (2b, 2c) which define the hollow interior (2a) of a terminal box body (2), a barrier wall (9) is arranged on the inside contiguous to the inserting portion (2d), and the connection cable (5) is press fitted to the inside of the inserting portion (2d) such that the opening of a recess formed in the barrier wall (9) in order to insert the connection cable (5) directs downward thus preventing molten resin filling the hollow interior (2a) from leaking. Furthermore, a first connection terminal (4b) for fixing the connection cable (5) previously by caulking, and a second connection terminal (4a) for soldering the output take-out wires (6a, 6b) of a solar cell module are press fitted in the terminal box body (2) thus saving the labor of field work such as the soldering work and the caulking work of cables or the output take-out wires of a solar cell module.

### TECHNICAL FIELD

The present invention relates to a terminal box for solar cell module used when connecting solar cell modules which constitute a solar electric power generating system for converting solar energy directly into electric energy in serial or in parallel with respect to each other, and a method of using the same.

### BACKGROUND ART

In the related art, as a known terminal box for solar cell module of this type, there is the one disclosed in Japanese Utility Model Registration No. 3069523, including a box-shaped box body having therein a pair of terminal boards being connected to a positive electrode and a negative electrode of the solar cell module, a bypass diode provided between both the terminal boards for preventing reverse current, and cables connected to both the terminal boards respectively for external connections, in which the connection of the bypass diode is achieved by fitting leads thereof to upright walls of the terminals and welding the same along the terminal boards in the longitudinal direction (see Patent Document 1).

As disclosed in JP-A-2000-349324, there is another known solar cell module including a terminal box body having an opening, the terminal box body having therein terminals to be connected to output take-out wires of the solar cell module and connecting pins provided on a sidewall of the terminal box body as connecting terminals for the connection of a wiring cable, in which the terminals to be connected to the output take-out wires and the connecting pins to be connected to the connecting cables are integrally formed (see Patent Document 2).

### Patent Document 1: Japanese Utility Model Registration No. 3069523

### Patent Document 2: JP-A-2000-349324

### DISCLOSURE OF INVENTION

### Problem to be Solved by the Invention

However, in the terminal box for solar cell module in the related art, for example, there are many points of welding such as diodes, connecting terminals, and output take-out wires and, in addition, the welding operation is performed in the terminal box. Therefore, it takes a lot of trouble and there is a risk of fusing and giving damages to the interior of the terminal box formed of synthetic resin by a soldering gun during the welding operation. In addition, it is necessary to fill insulative resin in the interior of the terminal box to provide the same with a waterproof structure and a dust-proof structure, so that there arises a risk that the insulative resin leaks out through insertion holes of the connecting cables when being filled. The terminal box for solar cell module according to the invention is proposed for solving the problems described above.

### Means for Solving the Problem

A terminal box for solar cell module according to the invention includes: an insulative terminal box body having a hollow interior, a bottom portion, and an opening formed on the bottom portion so as to communicate with the hollow interior; a sidewall that defines the hollow interior, a first connecting terminal and a second connecting terminal provided in the hollow interior and fixedly press-fitted to the bottom portion; a connecting cable fixedly connected to the first connecting terminal; an output take-out wire of the solar cell module to be led from the opening into the hollow interior and fixedly connected to the second connecting terminal; an inserting portion formed on the sidewall so as to allow passage of the connecting cable for leading out the connecting cable from the hollow interior, and the hollow interior to be filled with insulative melting resin and solidified. The inserting portion is formed into a recessed-shape opened on an upper side of the sidewall so as to allow fitting of the connecting cable from the side portion thereof, and the first connecting terminal is formed with a crimping portion for fixedly crimping the connecting cable. A barrier wall formed of synthetic resin is disposed at a position inside the sidewall and adjacent to the inserting portion, and the barrier wall is formed with a substantially U-shaped recess for allowing insertion of the connecting cable. A press-fitted portion where the barrier wall is press-fitted is formed at a position inside the sidewall and adjacent to the inserting portion, and the barrier wall is press-fitted into the press-fitted portion with an opening of the substantially U-shaped recess faced downward. Furthermore, the substantially U-shaped recess has an inner diameter smaller than the outer diameter of the connecting cable when the barrier wall is press-fitted into the press-fitted portion so as to prevent the insulative melting resin from leaking when being filled into the hollow interior.

In order to make the inner diameter of the substantially U-shaped recess formed on the barrier wall have an inner diameter smaller than the outer diameter of the connecting cable when the barrier wall is press-fitted into the press-fitted portion, the substantially U-shaped recess having an inner diameter smaller than the outer diameter of the connecting cable may be formed in advance. Alternatively, the barrier wall may be formed with the substantially U-shaped recess having an inner diameter larger than the outer diameter of the connecting cable and a protruding portion on the outside thereof, whereby the inner diameter of the substantially U-shaped recess may be reduced to be smaller than the outer diameter of the connecting cable by the protruding portions being pressed inward by the press-fitted portion when the barrier wall is press-fitted into the press-fitted portion.

A method of using a terminal box for solar cell module according to the invention includes the steps of: forming an opening on a bottom portion of an insulative terminal box body having a hollow interior so as to communicate with the hollow interior; forming a sidewall that defines the hollow interior; forming an inserting portion on the sidewall for leading out a connecting cable; fixedly disposing a first connecting terminal, the connecting cable to be connected to the first connecting terminal, a second connecting terminal, and an output take-out wire of the solar cell module led from the opening into the interior and connected to the second connecting terminal respectively in the hollow interior; subsequently, filling insulative melting resin into the hollow interior and solidifying the same; and closing the terminal box body with a lid member. The inserting portion is formed into a recessed-shape opening on an upper side thereof so that the connecting cable can be fitted therein from the side portion thereof, the first connecting terminal and the connecting cable are assembled by crimping the connecting cable with a crimping portion formed on the first connecting terminal, and the connecting cable is attached by being inserted into the recess on the barrier wall. The second connecting terminal and the first connecting terminal to which the connecting cable is connected are fixedly press-fitted into the bottom portion in the hollow interior. The connecting cable is fitted to the inserting portion formed into the recessed-shape and is led out and, simultaneously, the barrier wall including the connecting cable attached thereto is press-fitted to the press-fitted portion formed inside the sidewall and adjacent to the inserting portion with the opening of the recess faced downward so that the insulative melting resin is prevented from leaking out from the hollow interior when being filled.

### ADVANTAGES OF THE INVENTION

According to the terminal box for solar cell module and the method of using the same of the invention, the assembling operation of the terminal box in use is achieved easily by forming the sub-assembly by crimping the first connecting terminal and the connecting cable with the crimping portion in advance. In order to do so, the inserting portion is formed into the U-shaped recessed shape to enable mounting of the connecting cable from above. Accordingly, the number of points to be soldered in the hollow of the terminal box body is reduced, and hence the possibility of erroneous operation caused by welding is reduced.

Also, by using the barrier wall, the insulative melting resin is prevented from leaking out from the gap between the inserting portion formed on the sidewall that defines the hollow interior and the connecting cable. The inner diameter of the substantially U-shaped recess formed on the barrier wall is set to be smaller than the outer diameter of the connecting cable, or the recess is formed with the protruding portion on the outside thereof so as to reduce an inner diameter thereof to be smaller than the outer diameter of the connecting cable by being pressed by the sidewall of the press-fitted portion, so that the gap between the connecting cable and the recess on the barrier wall is eliminated, and the leakage of the insulative melting resin is prevented.

### BRIEF DESCRIPTION OF DRAWINGS

FIG. 1A is a plan view of a terminal box for solar cell module according to the invention in use in a state in which a lid member is removed.

FIG. 1B is a plan view of the terminal box for solar cell module according to the invention in use in a state in which the lid member is included.

FIG. 1C is a side view of the terminal box for solar cell module according to the invention in use in the state in which the lid member is included.

FIG. 2 is a cross-sectional view taken along the line A-A in FIG. 1B.

FIG. 3A is a plan view of a second connecting terminal for an output take-out wire.

FIG. 3B is a side view of the second connecting terminal for the output take-out wire.

FIG. 4A is a front view of a first connecting terminal for a connecting cable.

FIG. 4B is a plan view of the first connecting terminal for the connecting cable.

FIG. 4C is a side view of the first connecting terminal for the connecting cable.

FIG. 5A is a front view of a barrier wall of the terminal box for solar cell module.

FIG. 5B is a side view of the barrier wall of the terminal box for solar cell module.

FIG. 5C is a back view of the barrier wall of the terminal box for solar cell module.

FIG. 5D is a cross-sectional view of the barrier wall taken along the line X-X in FIG. 5A.

FIG. 5E is a cross-sectional view of the barrier wall taken along the line Y-Y in FIG. 5A.

FIG. 6A is a schematic view for explaining a fitted state between the connecting cable and the barrier wall when the barrier wall is formed with a recess having an inner diameter smaller than the outer diameter of the connecting cable.

FIG. 6B is a schematic view for explaining a fitted state between the connecting cable and the barrier wall when the barrier wall is formed with a recess having an inner diameter larger than the outer diameter of the connecting cable and a protruding portion on the outer side thereof.

FIG. 7 is a plan view of the connecting cable connected and fixed to the first connecting terminal, showing the position of connection of a connecting bar or a bypass diode by a dashed line.

FIG. 8 is a front view of a diode device for explaining that excessive portions of a lead are cut from the diode device to form connecting bars, and the bypass diode used in the invention is formed by cutting off the excessive portions.

FIG. 9A is a plan view showing a terminal box body in a state in which the second connecting terminal is press-fitted.

FIG. 9B is a central cross-sectional view showing the terminal box body in a state in which the second connecting terminal on the back surface of the solar cell module is press-fitted.

### REFERENCE NUMERALS

1 terminal box for solar cell module
2 terminal box body
2a hollow interior
2b, 2c sidewalls
2d inserting portion
2e press-fitted portion
3 bottom portion
3a opening
4a second connecting terminal
4b first connecting terminal
4c connecting bar
4d bypass diode
4e crimping portion
4f solder terminal portion
4g press-fitted projection
5 connecting cable
6a, 6b output take-out wire
7 insulative melting resin
8 reserve solder
9 barrier wall
9a recess
9b protruding portion
9c press-fit margin
9d disconnection preventing projection
10 lid member
11 solar cell module

### BEST MODE FOR CARRYING OUT THE INVENTION

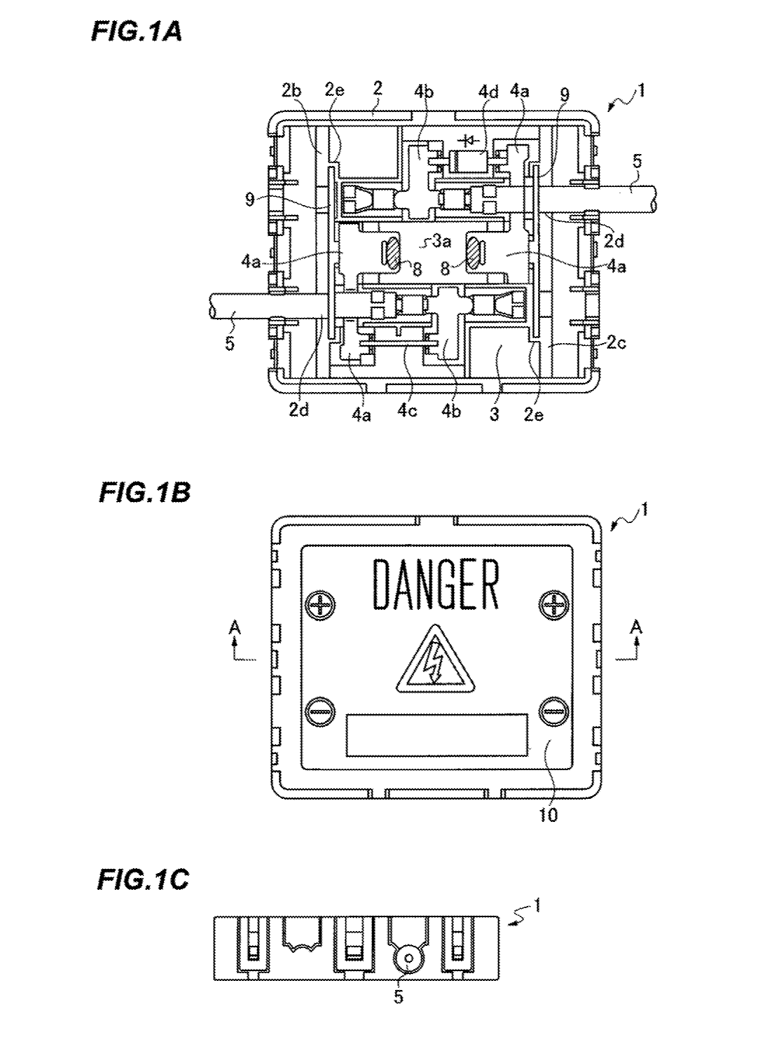

A terminal box 1 for solar cell module according to the invention is formed with an opening 3a which communicates with a hollow interior 2a on a bottom portion 3 of a terminal box body 2 formed integrally of insulative synthetic resin as shown in FIG. 1A.

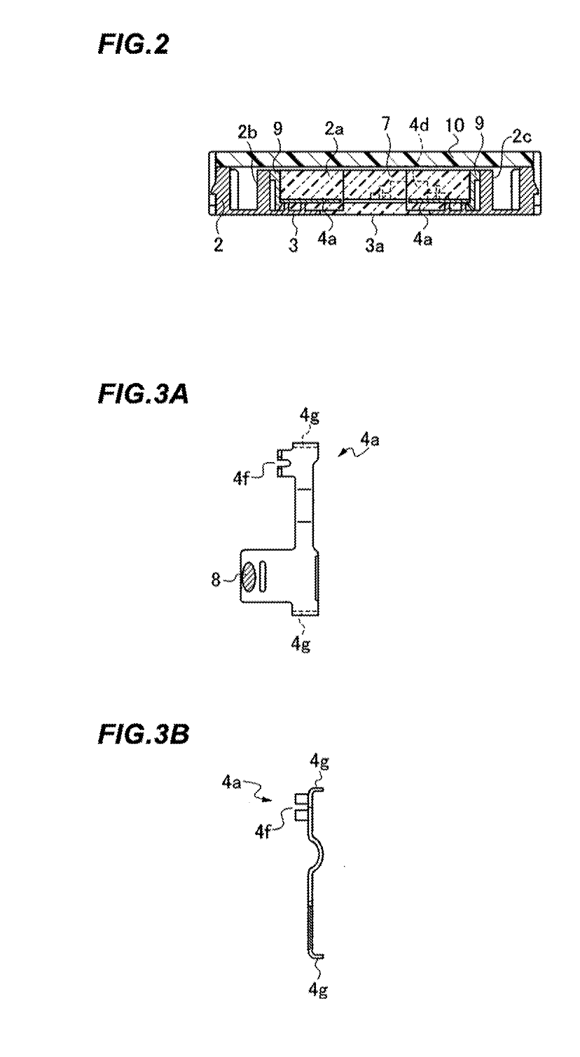

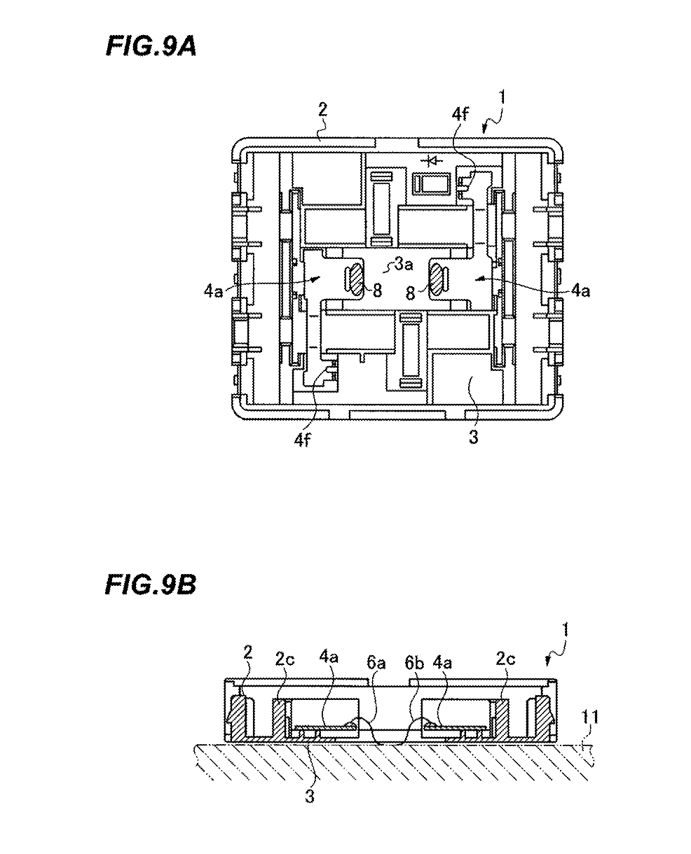

Sidewalls 2b, 2c which define the hollow interior 2a are formed with inserting portions 2d for leading out a connecting cable 5. Disposed in the hollow interior 2a and fixed to the bottom portion 3 respectively are first connecting terminals 4b, the connecting cables 5 connected to the first connecting terminal 4b, second connecting terminals 4a, and output take-out wires 6a, 6b of the solar cell module drawn into the interior from the opening 3a and connected to the second connecting terminals 4a as shown in FIG. 9B. In a state in which they are fixed, insulative melting resin 7 as potting resin is filled into the hollow interior 2a of the terminal box 1 and solidified as shown in FIG. 2.

The sidewalls 2b, 2c of the terminal box body 2 are formed with the inserting portions 2d each having a recessed-shape opened on an upper side thereof so as to allow fitting of the side portion of the connecting cable 5 therein by inserting the same from above. Therefore, the fitting operation is achieved easily in comparison with the operation in the related art that requires inserting the cable into an insertion hole from the end in the axial direction. The first connecting terminal 4b is formed with a crimping portion 4e for fixedly crimping an end of the connecting cable 5 in advance.

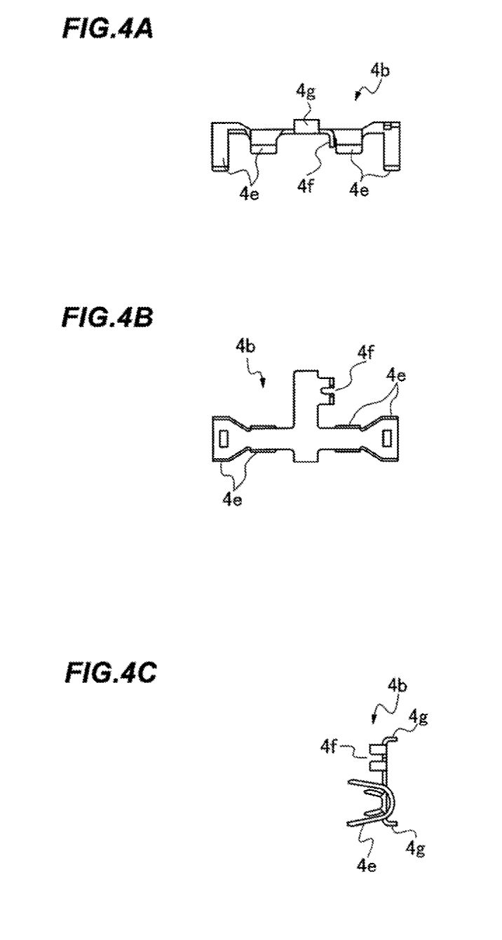

As shown in FIG. 1A, the two first connecting terminals 4b, 4b are disposed in the terminal box 1. Each first connecting terminal 4b includes the crimping portions 4e, 4e at two points, namely, at both ends as shown in FIGS. 1A, 4A, 4B, and 4C. In the example shown in FIG. 1A, the connecting cable 5 is crimped to only one of the crimping portions 4e, 4e at two points, namely, at both ends. However, the connecting cables 5, 5 may be connected to both of the crimping portions 4e, 4e of the respective first connecting terminals 4b, respectively, according to the specifications.

As shown in FIG. 3A, the second connecting terminal 4a includes a reserve solder 8 disposed at a position where the output take-out wire 6a or 6b is to be soldered. As shown in FIGS. 3A and 3B, press-fitted projections 4g, 4g to be press-fitted into the bottom portion 3 of the terminal box body 2 are formed at two points of the second connecting terminal 4a. The second connecting terminal 4a is formed with a solder terminal portion 4f for soldering a connecting bar 4c, which is a cut-off excessive portion of a lead from a diode device as shown in FIG. 8, or an end of a bypass diode 4d after having cut off the excessive portion of the lead from the diode device. In addition, the first connecting terminal 4b of the connecting cable is formed, in addition to the crimping portions 4e, 4e, with the press-fitted projections 4g, 4g for press-fitting the first connecting terminal 4b into the bottom portion 3 of the terminal box 1, and the solder terminal portion 4f to which the other end portion of the connecting bar 4c or the bypass diode 4d is to be soldered.

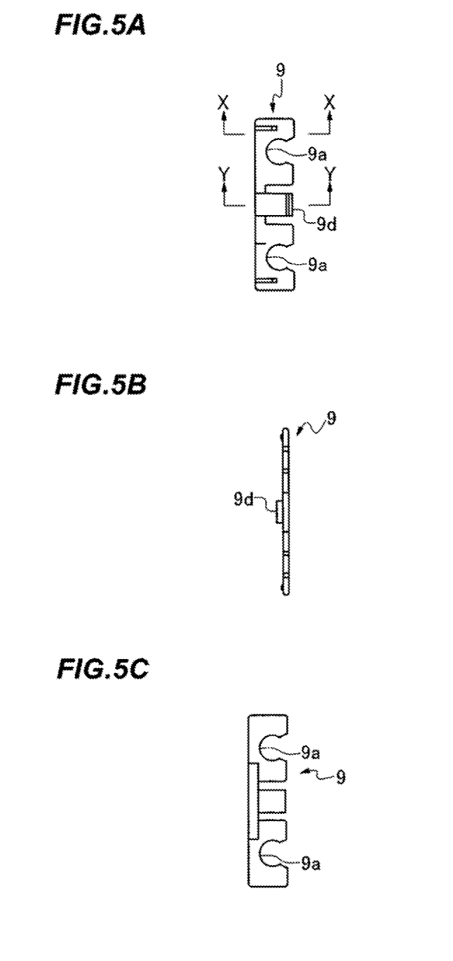

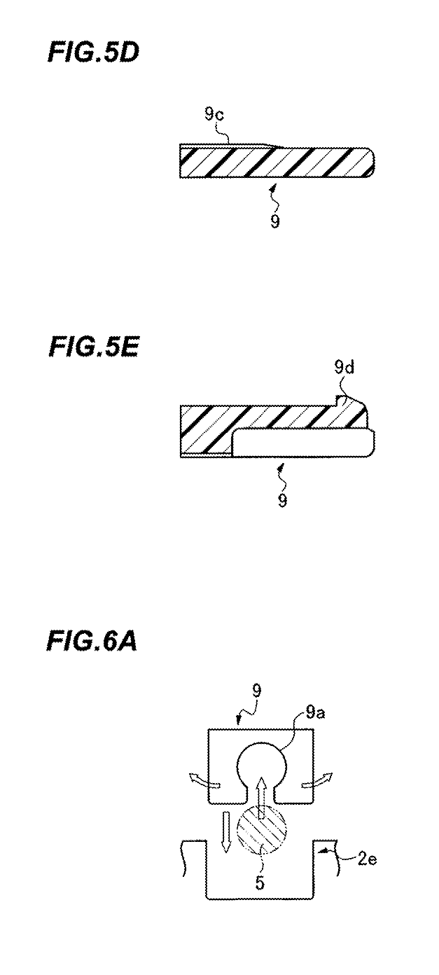

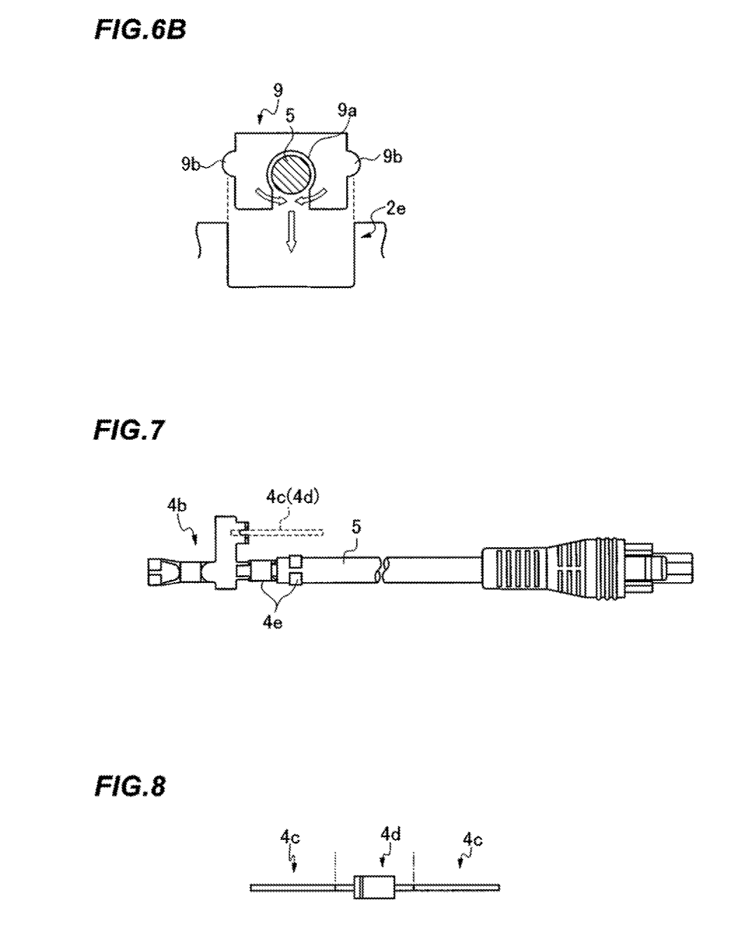

The terminal box body 2 is formed with press-fitted portions 2e to which barrier walls formed of synthetic resin are press-fitted on the inner sides of the inserting portions 2d. The barrier walls 9 each having recesses 9a for insertion as shown in FIG. 5A to FIG. 5C and FIG. 6A or FIG. 6B are press-fitted into the press-fitted portions 2e. Here, in order to prevent the insulative melting resin 7 from leaking from the hollow interior 2a, each inserting recess 9a has an inner diameter smaller than the outer diameter of the connecting cable 5 in a state of being press-fitted into the press-fitted portion 2e.

Making each recess 9a of the barrier wall 9 having an inner diameter smaller than the outer diameter of the connecting cable 5 in the state of being press-fitted into the press-fitted portion 2e is achieved by forming the recess 9a having an inner diameter smaller than the outer diameter of the connecting cable 5 as shown in FIG. 6A and, in addition, is also achieved by forming the recess 9a having an inner diameter larger than the outer diameter of the connecting cable 5 and forming protruding portions 9b on the outside portions of the barrier wall 9 as shown in FIG. 6B. In other words, it is achieved in such a manner that when the barrier wall 9 having the connecting cable 5 fitted therein is press-fitted into the press-fitted portion 2e, the protruding portions 9b are pressed inward, and the inner diameter of the recess 9a is reduced. Depending on the wiring of the connecting cable 5, the recess 9a may be provided at one position or at two positions. The barrier wall 9 is formed with a press-fit margin 9c as shown in FIG. 5D for achieving a tight-contact state without play between the barrier wall 9 and the press-fitted portion 2e when the barrier wall 9 is press-fitted therein, and a disconnection preventing projection 9d as shown in FIG. 5E for latching the barrier wall 9 after having press-fitted.

A manner of assembling the terminal box 1 for solar cell module according to the invention configured as described above for use will be described. First of all, as shown in FIG. 7, a core wire at an end of the connecting cable 5 is pulled out, the core wire is crimped with the crimping portion 4e of the first connecting terminal 4b, and the resin coat on the outside is also crimped. An end of the connecting bar 4c, which is a cut-off excessive portion of the lead from the diode device as shown in FIG. 8, or an end of the bypass diode 4d after having cut off the excessive portion of the lead from the diode device is soldered to the solder terminal portion 4f of the first connecting terminal 4b.

The barrier wall 9 is attached by fitting the recess 9a of the barrier wall 9 formed of synthetic resin at a predetermined position of the connecting cable 5. In this manner, a sub-assembly including the connecting cable 5, the first connecting terminal 4b and the barrier wall 9 is formed separately from the terminal box body 2.

On the other hand, on the side of the terminal box body 2, a pair of the second connecting terminals 4a, 4a are arranged on the bottom portion 3 from the side of the hollow interior 2a and are fixedly press-fitted in symmetry with respect to each other as shown in FIG. 9A. Subsequently, ends of two sets of sub-assemblies each including the first connecting terminal 4b, the connecting cable 5, and the barrier wall 9 are fixed to the terminal box body 2 by press-fitting the first connecting terminals 4b each having the connecting cable 5 attached thereto to the bottom portion 3 from the side of the hollow interior 2a. Then, the connecting cables 5 are fitted to the inserting portions 2d of the side walls 2 from above and are led to the outside and, simultaneously, the barrier walls 9 are press-fitted into the press-fitted portions 2e formed inside the inserting portions 2d with openings of the recesses 9a of the barrier walls 9 faced downward. As shown in FIG. 1A, the two sets of sub-assemblies are arranged in symmetry with respect to each other. With the provision of the barrier walls 9, the gaps between the connecting cables 5 and the U-shaped inserting portions 2d of the sidewalls 2b, 2c are clogged, whereby the prevention of leakage of the insulative melting resin 7 is achieved.

The other ends of the connecting bar 4c and the bypass diode 4d of the sub-assemblies are soldered to the solder terminal portions 4f, 4f of the second connecting terminals 4a, 4a for the output take-out wires, respectively.

Then, as shown in FIG. 9B, the terminal box body 2 having the sub-assemblies attached thereto is placed on the back surface of a solar cell module 11 and the output take-out wires 6a, 6b are led inside from the opening 3a. Then, the terminal box body 2 having the sub-assemblies attached thereto is fixed to the solar cell module using an adhesive agent. Subsequently, the output take-out wires 6a, 6b are soldered to the second connecting terminals 4a, 4a for the output take-out wires with the reserve solder 8 disposed on the second connecting terminals 4a, 4a in advance.

In this manner, in the terminal box 1 for solar cell module, soldering is performed at six points in total, that is, two points at the respective ends of the output take-out wires 6a, 6b, two points at the ends of the connecting bar 4c, and two points at the ends of the bypass diode 4d.

Subsequently, as shown in FIG. 2, the insulative melting resin 7 is filled into the hollow interior 2a and solidified, and then, the terminal box body 2 is closed by a lid member 10, so that the assembly of the terminal box 1 for solar cell module in the state for use is completed.

### INDUSTRIAL APPLICABILITY

The terminal box according to the invention can be used when connecting solar cell modules which constitute a solar electric power generating system for converting solar energy directly into electric energy in serial or in parallel with respect to each other.

1. A terminal box for solar cell module comprising:
an insulative terminal box body having a hollow interior, a sidewall that defines the hollow interior, a bottom portion, and an opening formed on the bottom portion so as to communicate with the hollow interior;
a first connecting terminal and a second connecting terminal arranged in the hollow interior and fixedly press-fitted to the bottom portion;
a connecting cable is fixedly connected to the first connecting terminal;
an output take-out wire of the solar cell module to be led from the opening into the hollow interior and fixedly connected to the second connecting terminal;
an inserting portion formed on the sidewall so as to allow passage of the connecting cable for leading out the connecting cable from the hollow interior, and
insulative melting resin filled into the hollow interior and solidified,
wherein the inserting portion is formed into a recessed-shape opened on an upper side of the sidewall so as to allow fitting of the connecting cable from the side portion thereof,
the first connecting terminal is formed with a crimping portion for fixedly crimping the connecting cable,
a barrier wall formed of synthetic resin is disposed at a position inside the sidewall and adjacent to the inserting portion,
the barrier wall is formed with a substantially U-shaped recess for allowing insertion of the connecting cable,
a press-fitted portion where the barrier wall is press-fitted is formed at a position inside the sidewall and adjacent to the inserting portion,
the barrier wall is press-fitted into the press-fitted portion with an opening of the substantially U-shaped recess faced downward, and
the substantially U-shaped recess has an inner diameter smaller than the outer diameter of the connecting cable when the barrier wall is press-fitted into the press-fitted portion so as to prevent the insulative melting resin from leaking when being filled into the hollow interior.

2. The terminal box for solar cell module according to claim 1, wherein the barrier wall is formed with the substantially U-shaped recess having an inner diameter smaller than the outer diameter of the connecting cable.

3. The terminal box for solar cell module according to claim 1, wherein the barrier wall is formed with the substantially U-shaped recess having an inner diameter larger than the outer diameter of the connecting cable and a protruding portion on the outside thereof, whereby the inner diameter of the substantially U-shaped recess is reduced to be smaller than the outer diameter of the connecting cable by the protruding portions being pressed inward by the press-fitted portion when the barrier wall is press-fitted into the press-fitted portion.

4. A method of using a terminal box for solar cell module having the steps of:
forming an opening on a bottom portion of an insulative terminal box body having a hollow interior so as to communicate with the hollow interior; forming a sidewall that defines the hollow interior; forming an inserting portion on the sidewall for leading out a connecting cable; fixedly disposing a first connecting terminal, the connecting cable to be connected to the first connecting terminal, a second connecting terminal, and an output take-out wire of the solar cell module led from the opening into the interior and connected to the second connecting terminal respectively in the hollow interior;
subsequently, filling insulative melting resin into the hollow interior and solidifying the same; and
closing the terminal box body with a lid member; comprising:
assembling the connecting cable to the first connecting terminal by crimping an end of the connecting cable with a crimping portion formed on the first connecting terminal;
attaching the barrier wall to the connecting cable in such a manner that the side portion of the connecting cable is fitted to a substantially U-shaped recess formed on the barrier wall;
inserting the side portion of the connecting cable into the inserting portion formed into a recessed-shape opening on an upper side thereof by fitting the same from an opening thereof;
fixedly press-fitting the first connecting terminal including the connecting cable connected thereto to the bottom portion from the side of the hollow interior; and
fitting the connecting cable into the inserting portion formed into the recessed-shape and leading out the same and, simultaneously, press-fitting the barrier wall including the connecting cable attached thereto to the press-fitted portion formed inside the sidewall and adjacent to the inserting portion with the opening of the recess faced downward so as to prevent the insulative melting resin from leaking out from the hollow interior when being filled.

5. The method of using a terminal box for solar cell module according to claim 4, wherein the recess on the barrier wall is formed into a substantially U-shape having an inner diameter smaller than the outer diameter of the connecting cable.

6. The method of using a terminal box for solar cell module according to claim 4, wherein the recess on the barrier wall is formed into the substantially U-shape having an inner diameter larger than the outer diameter of the connecting cable and a protruding portion is formed on the outside of the barrier wall, and the inner diameter of the substantially U-shaped recess is reduced to be smaller than the outer diameter of the connecting cable by the protruding portions being pressed inward by the press-fitted portion when the barrier wall is press-fitted into the press-fitted portion.
